(19) United States
(12) Patent Application Publication
(10) Pub. No.: US 2007/0277997 A1
(43) Pub. Date: Dec. 6, 2007

(54) SUBSTRATE AND LAYOUT METHOD

(76) Inventors: Wei-An Liang, Hsin-Chu City (TW); Chung-Ju Wu, Kao-Hsiung City (TW); Yin-Chieh Hsueh, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/421,481

(22) Filed: Jun. 1, 2006

(51) Int. Cl. H05K 1/03

(52) U.S. Cl. 174/255; 29/846

(57) ABSTRACT

Layout methods for a substrate are disclosed. In one embodiment, the method includes: defining a first plating line on a non-conducting layer coupled to a first pad; and defining a second plating line on the first conducting layer coupled to a second pad. Along a direction away from the first pad and the second pad, a distance between the first plating line and the second plating line becomes longer. In another embodiment, the method includes: defining a plating line on a non-conducting layer, the plating line being coupled to a pad; and replacing a portion of at least a conducting layer with a non-conducting material, wherein the portion is directly under the plating line.

### BACKGROUND OF THE INVENTION

1. Field of the Invention

The present invention provides a substrate and layout method thereof, and more particularly, to a substrate with a plating line and layout method thereof.

2. Description of the Prior Art

In conventional ICs packaging fabrication, core devices such as a die are attached on a substrate including non-conducting layers and conducting layers. In which, the number of layers depends on the packaging process that applied to the design. The non-conducting layer (i.e., a dielectric layer) is used as an insulating layer between conducting layers. As semiconductor circuits operate under control of a faster clock and become more compact, operating frequencies increase and the distances between the conducting lines within the package decrease. This introduces an increased level of coupling parasitic capacitance to the conducting lines, which has the drawback of slowing the operation of the semiconductor device. Generally, conducting lines made of metals are formed on the surface of a conventional package substrate such as ball grid array package.

Typically, the exposed surface of the electrical connecting pads must be plated with a metal layer such as a Nickel/Gold (Ni/Au) or Nickel/Silver (Ni/Ag) layer to electrically connect the conducting lines to the chip. In order to plate a Ni/Au metal layer on the electrical connecting pad, it is necessary to dispose a plurality of well-known plating lines on the surface of the substrate to supply electric current for electroplating the Ni/Au layer onto the electrical connecting pad. Moreover, the plating lines may result in large parasitic capacitance formed between the plating lines and the conducting layer below the plating lines. Etching the plating lines after electroplating the connecting pad is an effective way to solve the aforementioned problem caused by the undesired parasitic capacitance. However, it is expensive for etching the plating lines. Furthermore, in a differential signal module, the doubled plating line densities will increase the undesired coupling parasitic capacitance when the differential signal module operates at high operating frequency. Hence, there is a need for a cheaper and improved method to solve the above-mentioned problems.

### SUMMARY OF THE INVENTION

It is therefore one of the objectives of the claimed invention to provide a substrate and layout method thereof.

According to an embodiment of the claimed invention, a layout method for a substrate is disclosed. The layout method comprises: defining a first plating line on a non-conducting layer coupled to a first pad; and defining a second plating line on the non-conducting layer coupled to a second pad; wherein along a direction away from the first pad and the second pad, a distance between the first plating line and the second plating line becomes longer.

According to an embodiment of the present invention, a layout method for a substrate is disclosed. The layout method comprises: defining a plating line on a non-conducting layer coupled to a pad; and replacing a portion of at least a conducting layer under the non-conducting layer with a non-conducting material, wherein the portion is directly under the plating line.

According to an embodiment of the claimed invention, a substrate is disclosed. The substrate comprises: a first plating line formed on a non-conducting layer and coupled to a first pad; and a second plating line formed on the non-conducting layer and coupled to a second pad; wherein along a direction away from the first pad and the second pad, a distance between the first plating line and the second plating line becomes longer.

According to an embodiment of the present invention, a substrate is disclosed. The substrate comprises: a plating line formed on a non-conducting layer coupled to a first pad; and at least a conducting layer under the non-conducting layer, where the conducting layer has a portion formed by a non-conducting material, and the portion is directly under the first plating line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-section view of a substrate according to an embodiment of the present invention.

FIG. 2 is a perspective view of the substrate shown in FIG. 1.

FIG. 3 illustrates a top view of a substrate according to an embodiment of the present invention.

FIG. 4 is flowchart illustrating a first layout method according to the present invention.

FIG. 5 is a flowchart illustrating a second layout method according to the present invention.

FIG. 6 is flowchart illustrating a third layout method according to the present invention.

### DETAILED DESCRIPTION

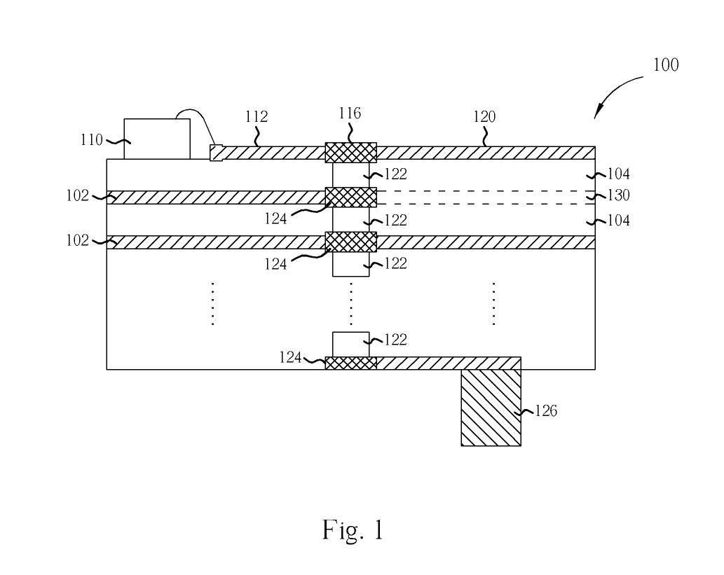

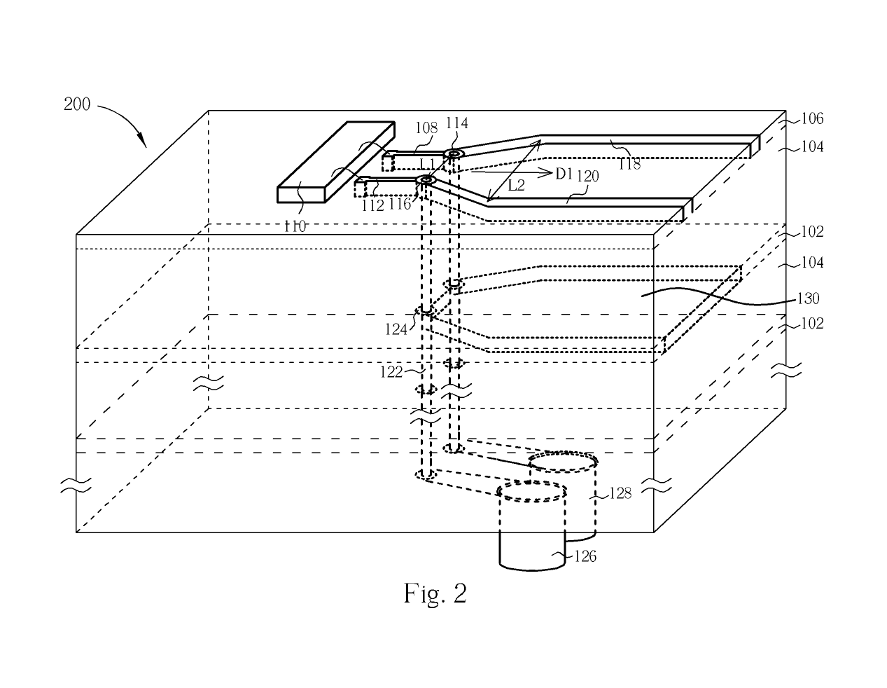

Please refer to FIG. 1 in conjunction with FIG. 2. FIG. 1 illustrates a cross-section view of a substrate 100 according to an embodiment of the present invention. FIG. 2 illustrates a perspective view of the substrate 100 shown in FIG. 1. In this embodiment, the substrate 100 is a BGA substrate; however, the present invention is not limited to this substrate type. The substrate 100 comprises metal layers (i.e., conducting layers 102) and dielectric layers (i.e., non-conducting layers 104, 106). In addition, the substrate 100 further comprises a die 110 attached to a surface of a non-conducting layer 106, a first metal line 108, a second metal line 112, a first pad 14, a second pad 116, a first plating line 118, and a second plating line 120. In which, first metal line 108 is formed on the non-conducting layers 104 for coupling a first signal of the differential output signal pair from the die 110. Second metal line 112 is formed on the first conducting layer 106 for coupling a second signal of the differential output signal pair from the die 110. The first plating line 118 formed on the first conducting layer 106 for coupling the first metal line 108 and for supplying electric current for electroplating a conducting material to form the first pad 114. The second plating line 120 formed on the non-conducting layer 106 for coupling the second metal line 112 and for supplying electric current for electroplating a conducting material to form the second pad 116. Please note that the number of lines and the number of layers shown in FIG. 1 and FIG. 2 are not limited to those illustrated. Additionally, the shape and location of the lines shown in FIG. I and FIG. 2 are for illustrative purposes and are not meant to be construed as limitations of the present invention.

There are a plurality of interlaced vias 122 and pads 124 positioned directly below the first pad 114 and the second pad 116 to transmit signal to a first package output node 126 and second package output node 128, respectively. In other words, vias 122 are formed within non-conducting layers 104 and pads 124 are formed within conducting layers 102.

According to the embodiment of the present invention, the first pad 114 and the second pad 116 are separated by a first distance L1. As shown in FIG. 2, it is clear that along a direction D1 away from the first pad 114 and the second pad 116, a distance L2 between the first plating line 118 and the second plating line 120 becomes longer. Furthermore, the present invention replaces a portion of the conducting layer 102 to be the conducting layer 130 under the non-conducting layer 106 with a non-conducting material, wherein the portion is formed directly under the first plating line 118 and the second plating line 120 and provides no influence to the normal transmitting function of the substrate 100.

A greater distance L2 will consequently boost the input impedance of the first and second plating lines 118, 120. Therefore, when the input impedance of the first and second plating lines 118, 120 increases, the input impedance of the first and second plating lines 118, 120 are more like an open circuit that will be equivalent to two etched plating lines formed by the prior art etching back process. Accordingly, the manufacturing cost can be reduced. In practice, the gradually increasing distance L2 will consequently improve the insertion loss inputted into the first and second package output nodes 126 and 128. According to the capacitance equation, parasitic capacitance C is as below:

C=−εA/d Equation (1)

In the above equation (1), ε represents the dielectric constant of material between the two conducting layers 102, A represents equivalent area of the parasitic capacitor, and d represents the distance between two the conducting layers 102. Therefore, replacing a portion of the conducting layer 102 under the non-conducting layer 106 with a non-conducting material will substantially double the distance d and therefore halve the undesired parasitic capacitance C. As a result, the output signal can be transmitted through the BGA package and forwarded to a next electronic device while incurring reduced loss.

Please note that the methods that described in FIG. 2 are merely an embodiment and are not limitation of the present invention. In the other words, the above-mentioned methods can be implemented independently and not limited in differential module. For the example, an embodiment can be just the method along a direction D1 away from the first pad 114 and the second pad 116, a distance L2 between the first plating line 118 and the second plating line 120 becomes longer but without replacing a portion of the conducting layer 102 under the non-conducting layer 106 with a non-conducting material. For another example, an embodiment can be just replacing the portion of the conducting layer 102 under non-conducting layer with a non-conducting material, wherein the portion is an area just positioned directly under the first plating line 118.

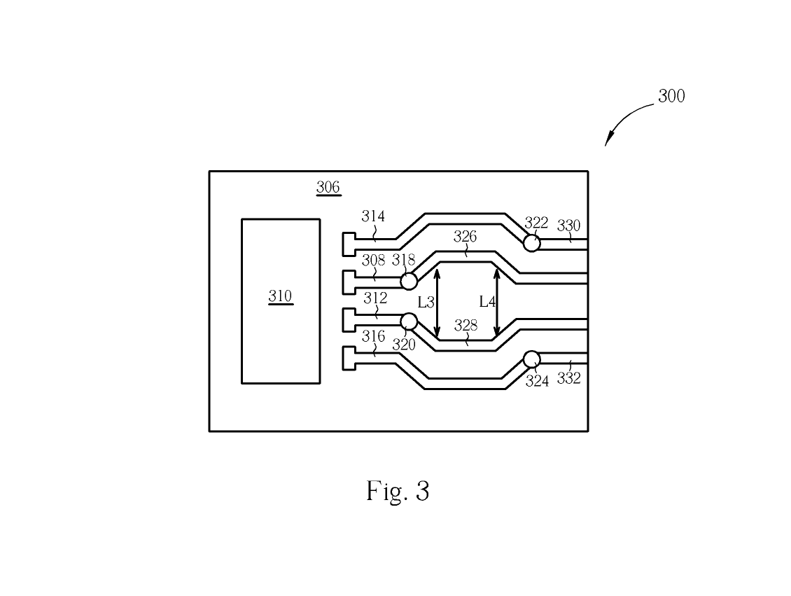

FIG. 3 illustrates a top view of a substrate 300 according to an embodiment of the present invention. The substrate 300 comprises a die 310 attached to a surface of a non-conducting layer 306, a first metal line 308, a second metal line 312, a third metal line 314, a fourth metal line 316, a first pad 318, a second pad 320, a third pad 322, a fourth pad 324, a first plating line 326, a second plating line 328, a third plating line 330, and a fourth plating line 332. The operation of substrate 300 is largely the same as the substrate 100, except that there has another pair of plating lines and pads. According to the present invention, where along a direction away from the first pad 318 and the second pad 320, a distance L3 between the first plating line 326 and the second plating line 328 becomes longer, but in order to save the total area of the substrate 300, a distance L4 between the first plating line 326 and the second plating line 328 becomes smaller when approaches to the third and fourth pads 322, 324.

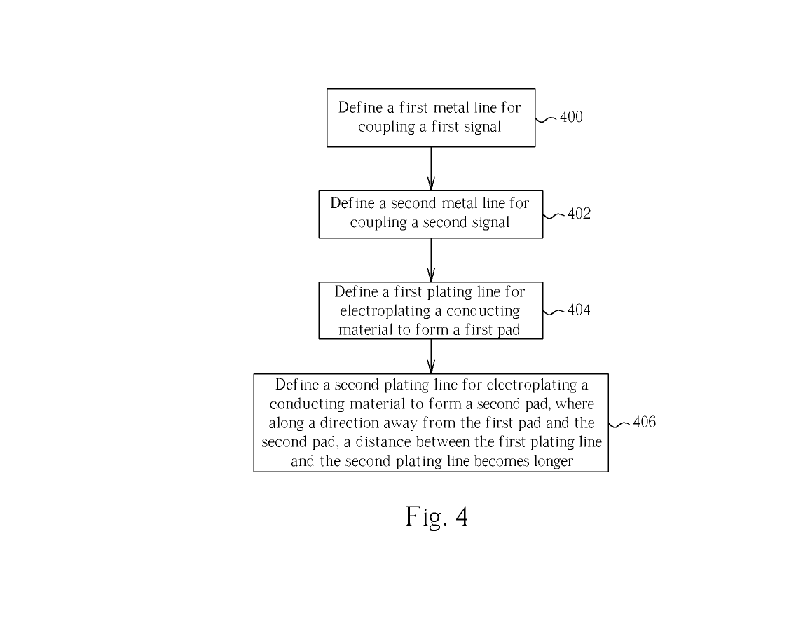

FIG. 4 is flowchart illustrating a first layout method according to the present invention. The first layout method can be applied to reduce the undesired parasitic capacitance in a substrate, such as a BGA substrate. For example, the substrate 100 shown in FIG. 1 and FIG. 2 contains the layout configuration defined by the first layout method. Referencing the aforementioned description, the first layout method is briefly described below:

Step 400: Define a first metal line on a non-conducting layer for coupling a first signal from a die;

Step 402: Define a second metal line on the non-conducting layer for coupling a second signal from the die;

Step 404: Define a first plating line on the non-conducting layer for coupling the first metal line and for supplying electric current for electroplating a conducting material to form a first pad; and

Step 406: Define a second plating line on the non-conducting layer for coupling the second metal line and for supplying electric current for electroplating a conducting material to form a second pad, where along a direction away from the first pad and the second pad, a distance between the first plating line and the second plating line becomes longer.

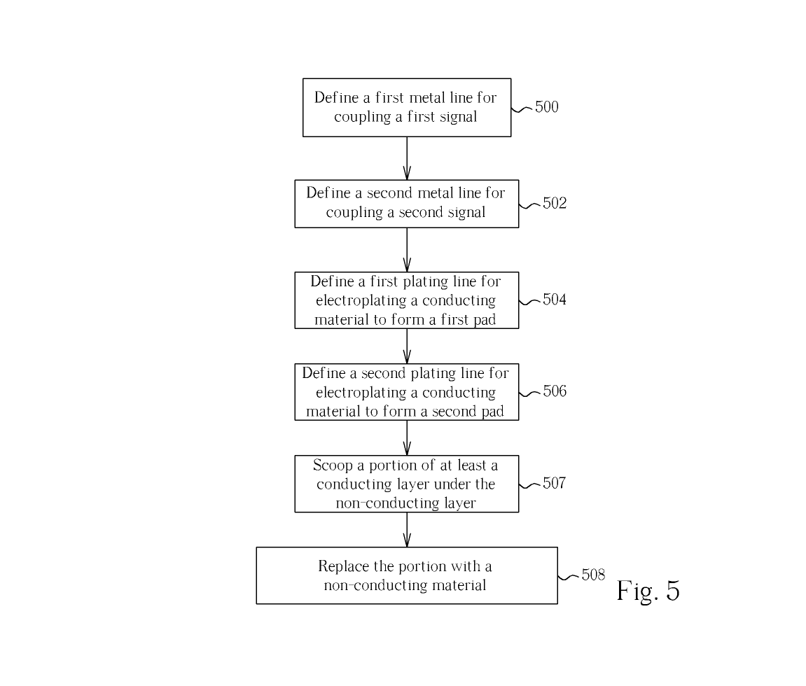

FIG. 5 is a flowchart illustrating a second layout method according to the present invention. The second layout method can be applied to reduce the undesired parasitic capacitance in a substrate. For example, the substrate 100 shown in FIG. 1 and FIG. 2 contains the layout configuration defined by the second layout method. Referencing the aforementioned description, the second layout method is briefly described below:

Step 500: Define a first metal line on a non-conducting layer for coupling a first signal from a die;

Step 502: Define a second metal line on the non-conducting layer for coupling a second signal from the die;

Step 504: Define a first plating line on the non-conducting layer for coupling the first metal line and for supplying electric current for electroplating a conducting material to form a first pad;

Step 506: Define a second plating line on the non-conducting layer for coupling the second metal line and supplying electric current for electroplating a conducting material to form a second pad;

Step 507:Scoop a portion of at least a conducting layer under the non-conducting layer where the portion is directly formed under the first plating line and the second plating line; and

Step 508: Replace the portion with a non-conducting material.

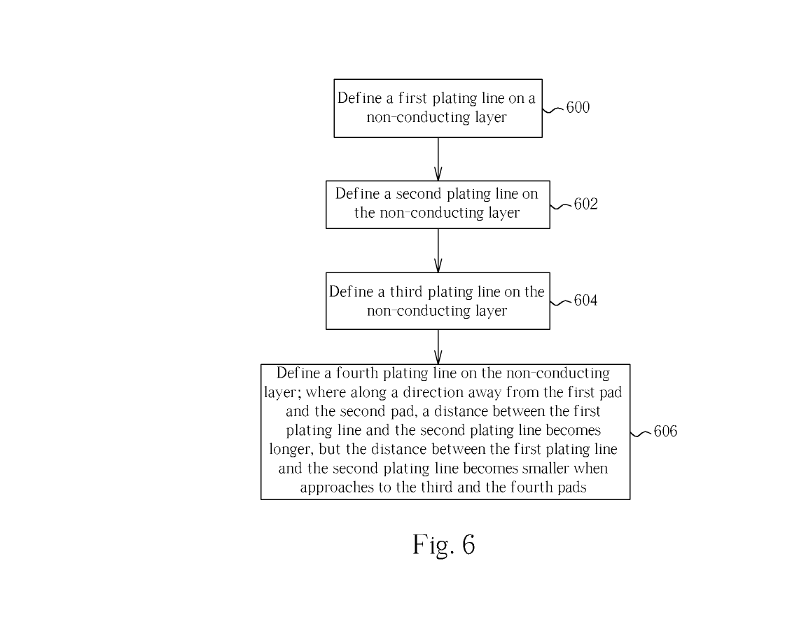

FIG. 6 is flowchart illustrating a third layout method according to the present invention. The third layout method can be applied to reduce the total area of a substrate. For example, the substrate 100 shown in FIG. 1 and FIG. 2 contains the layout configuration defined by the first layout method. Referencing the aforementioned description, the third layout method is briefly described below:

Step 600: Define a first plating line on a non-conducting layer for coupling a first metal line and for supplying electric current for electroplating a conducting material to form a first pad;

Step 602: Define a second plating line on the non-conducting layer for coupling a second metal line and for supplying electric current for electroplating a conducting material to form a second pad;

Step 604: Define a third plating line on the non-conducting layer for coupling a third metal line and for supplying electric current for electroplating a conducting material to form a third pad;

Step 606: Define a fourth plating line on the non-conducting layer for coupling a fourth metal line and for supplying electric current for electroplating a conducting material to form a fourth pad; where along a direction away from the first pad and the second pad, a distance between the first plating line and the second plating line becomes longer, but in order to save the total area of the substrate, the distance between the first plating line and the second plating line becomes smaller when approaches to the third and the fourth pads.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout method for a substrate comprising:
defining a first plating line on a non-conducting layer, the first plating line being coupled to a first pad; and
defining a second plating line on the non-conducting layer, the second plating line being coupled to a second pad;
wherein along a direction away from the first pad and the second pad, a distance between the first plating line and the second plating line becomes longer.

2. The method of claim 1, further comprising replacing a portion of at least a conducting layer under the non-conducting layer with a non-conducting material, wherein the portion is directly under the first plating line or the second plating line or both the first and second plating lines.

3. The method of claim 2, wherein the portion is directly under both the first and second plating lines, and an area of the portion is not less than a total area of the first plating line and the second plating line.

4. A layout method for a substrate comprising:
defining a plating line on a non-conducting layer, the plating line being coupled to a pad; and
replacing a portion of at least a conducting layer under the non-conducting layer with a non-conducting material, wherein the portion is directly under the plating line.

5. The method of claim 4, wherein an area of the portion is not less than an area of the plating line.

6. A substrate, comprising:
a first plating line formed on a non-conducting layer and coupled to a first pad; and
a second plating line formed on the non-conducting layer and coupled to a second pad;
wherein along a direction away from the first pad and the second pad, a distance between the first plating line and the second plating line becomes longer.

7. The substrate of claim 6, wherein at least a conducting layer under the non-conducting layer has a portion formed by a non-conducting material, and the portion is directly under the first plating line or the second plating line or both the first and second plating lines.

8. The substrate of claim 7, wherein the portion is directly under both the first and second plating lines, and an area of the portion is not less than a total area of the first plating line and the second plating line.

9. The substrate of claim 7, being a ball grid array substrate.

10. A substrate, comprising:
a plating line formed on a non-conducting layer and coupled to a first pad; and
at least a conducting layer under the non-conducting layer, the conducting layer having a portion formed by a non-conducting material, the portion being directly under the first plating line.

11. The substrate of claim 10, wherein an area of the portion is not less than an area of the first plating line.

12. The substrate of claim 10, being a ball grid array substrate.
